(19) United States
(12) Patent Application Publication
(10) Pub. No.: US 2015/0077908 A1
(43) Pub. Date: Mar. 19, 2015

(54) MODULAR ELECTRONIC DEVICE

(71) Applicant: Honda Motor Co., Ltd., Tokyo (JP)

(72) Inventors: Jessie Pearson, Oxford, AL (US); Douglas Jordan, Jacksonville, AL (US)

(73) Assignee: Honda Motor Co., Ltd., Tokyo (JP)

(21) Appl. No.: 14/028,585

(22) Filed: Sep. 17, 2013

(51) Int. Cl. H01B 17/58; H05K 5/02

(52) U.S. Cl. CPC H01B 17/583; H05K 5/0247
USPC 361/679.01; 29/592.1; 174/152 G

(57) ABSTRACT

A grommet for a modular electronic device includes a body including a first side and a second side opposite the first side. A head extends from the first side of the body. A channel extends through the body and the head. At least one buttress extends outward and along a length of the body. The buttress extends outward a first length adjacent the first side and a shorter second length adjacent the second side.

### BACKGROUND

An on-board diagnostic (OBD) system is a computer-based system that monitors the performance of various components on the vehicle. The vehicle has a vehicle diagnostic system, including one or more separate computer control modules, and upon detection of a malfunction, the OBD system provides the owner of the vehicle with an early warning of the malfunction. For example, a check engine light could be illuminated in the dashboard indicative of the malfunction. To investigate the malfunction, a data link cable or on-board diagnostic cable serves as a communications link between the vehicle's diagnostic port and an off-board diagnostic device. The typical OBD cable has one end with a multiple pin connector which connects to the vehicle data bus and the opposite end of the cable has a multiple pin connector which connects to the test unit. One of the problems with the current OBD cable is that it is non-repairable, and must be discarded if damaged.

### BRIEF DESCRIPTION

In accordance with one aspect, a grommet for a modular electronic device comprises a body including a first side and a second side opposite the first side. A head extends from the first side of the body. A channel extends through the body and the head. At least one buttress extends outward and along a length of the body. The buttress extends outward a first length adjacent the first side and a shorter second length adjacent the second side.

In accordance with another aspect, an electronic device comprises a housing including an aperture therein and a grommet. The grommet comprises a body positioned entirely outside of the housing. A head extends from the body and is at least partially received in the aperture of the housing. A passage extends through the body and head. At least one buttress extends substantially perpendicularly outward from the body and is engagable with an outer wall of the housing. A cable extends through the channel.

In accordance with yet another aspect, a method of installing an electrical cord to an electronic device housing comprises providing a removable grommet on the cable, the grommet comprising a body, a head extending from the body, a channel extending through the body and the head, and at least one buttress extending substantially perpendicularly outward from the body; inserting a first end of the cable through the channel of the grommet; connecting the first end of the cable to the housing; and inserting the head of the grommet into a corresponding aperture provided on the housing.

### BRIEF DESCRIPTION OF THE DRAWINGS

FIG. 1 is a view of an exemplary modular electronic device according to the present disclosure.

FIG. 2 is a partial cross-sectional view of an exemplary grommet of the modular electronic device of FIG. 1 according to one aspect of the present disclosure.

FIG. 3 is a perspective view of the exemplary grommet of the modular electronic device of FIG. 1.

FIG. 4 is a perspective view of an exemplary grommet of the modular electronic device of FIG. 1 according to another aspect of the present disclosure.

FIG. 5 is a perspective view of a removable/replaceable first connector of the modular electronic device of FIG. 1.

FIG. 6 is a perspective view of a removable/replaceable second connector of the modular electronic device of FIG. 1.

### DETAILED DESCRIPTION

It should, of course, be understood that the description and drawings herein are merely illustrative and that various modifications and changes can be made in the structures disclosed without departing from the present disclosure. In general, the figures of the exemplary modular electronic device are not to scale. It will also be appreciated that the various identified components of the exemplary modular electronic device disclosed herein are merely terms of art that may vary from one manufacturer to another and should not be deemed to limit the present disclosure.

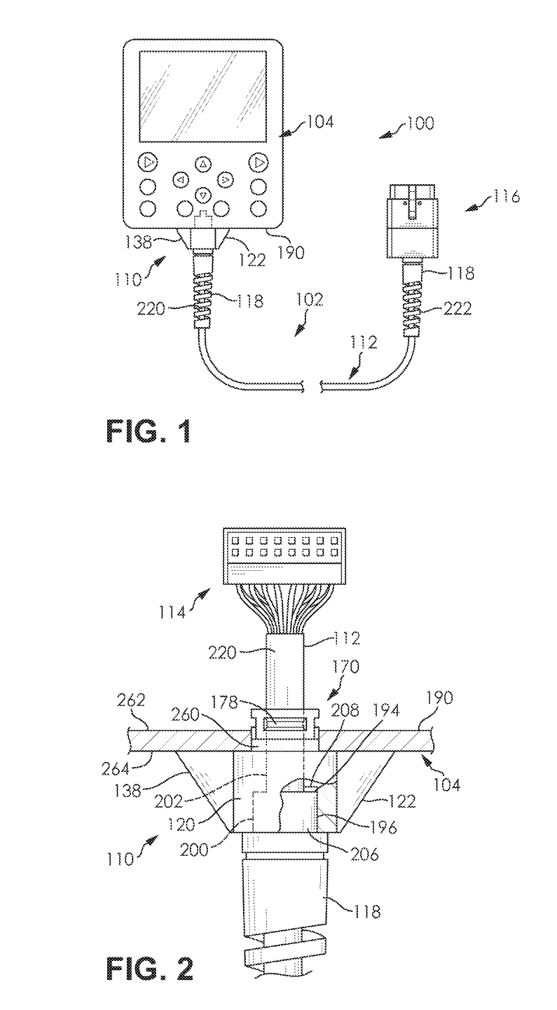

Referring now to the drawings, wherein like numerals refer to like parts throughout the several views, FIG. 1 illustrates an electronic assembly 100 including an electronic device 102, such as an on-board diagnostic (OBD) cable, operably connected to a second electronic device 104, such as an off-board diagnostic device. To investigate a vehicle malfunction, the electronic device 102 or OBD cable 102 serves as a communications link between the vehicle's diagnostic port (not shown) and the off-board diagnostic device 104. In contrast to a known OBD cable, the exemplary electronic device 102 includes a plurality of removable and replaceable components that allow the electronic device 102 to be repaired. The replaceable components can include a grommet 110, a cable 112, a first connector 114, a second connector 116, and at least one strain relief 118 provided on the cable adjacent to one of the first and second connectors 114, 116.

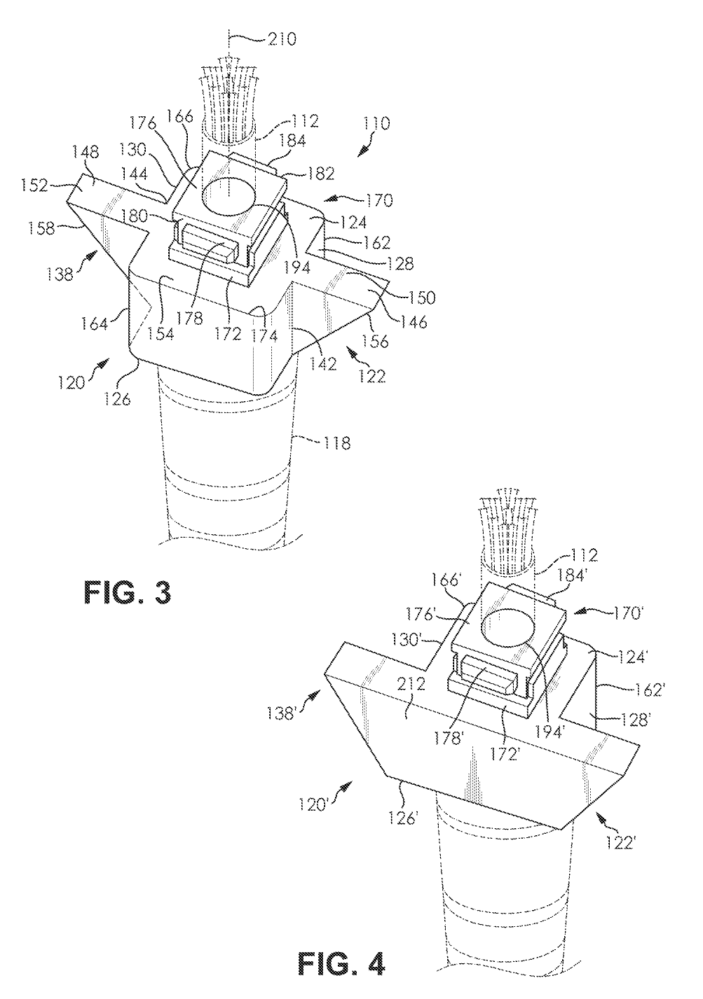

With reference to FIGS. 2 and 3, and according to one aspect, the exemplary grommet 110 comprises a body 120 and at least one buttress 122 extending outward and along a length of the body 120. As depicted, the body 120 can be generally rectangular shaped in cross-section and includes a first side 124 and a second side 126 opposite the first side 124. The body 120 further includes a third side 128 and a fourth side 130 opposite the third side 128. The third and fourth sides 128, 130 are oriented substantially perpendicular to and interconnect the first and second sides 124, 126. According to one aspect, the at least one buttress 122 is a first buttress and the grommet 110 further includes a second buttress 138 opposite the first buttress 122. The first buttress 122 extends outward and along a length of the third side 128 of the body 120. The second buttress 138 extends outward and along a length of the fourth side 130 of the body 120. The second buttress 138 can be shaped identical to the first buttress 122, and in the illustrated embodiment, each of the first and second buttresses 122, 138 extends outward a first length adjacent the first side 124 and a shorter second length adjacent the second side 126. With this configuration, each of the first and second buttresses 122, 138 can be generally triangular shaped in cross-section; although, this is not required.

Each of the first and second buttresses 122, 138 includes a respective first side 142, 144 and a respective second side 146, 148. The first side 142 of the first buttress 122 is secured to the third side 128 of the body 120. The second side 146 of the first buttress extends substantially perpendicularly from the first side 142. Similarly, the first side 144 of the second buttress 138 is secured to the fourth side 130 of the body 120, and the second side 148 of the second buttress extends substantially perpendicularly from the first side 144. According to one aspect, the first and second buttresses 122, 138 are formed integrally with the body 120 to define a one-piece grommet 110. As shown, the second side 146, 148 of each of the first and second buttresses 122, 138 includes a respective surface 150, 152 which is coplanar with a contact surface 154 defined by the first side 124 of the body 120. Further, with the depicted triangular shaped configuration of the first and second buttresses 122, 138, each of the first and second buttresses 122, 138 includes a respective third side 156, 158 which spans between and interconnects the respective first sides 142, 144 and second sides 146, 148. As best depicted in FIG. 3, the first buttress 122 is spaced inwardly from opposite edges 160, 162 of the third side 128 of the body 120, and can be centrally located on the third side 128. The second buttress 138 is spaced inwardly from opposite edges 164, 166 of the fourth side 130 of the body 120, and can be centrally located on the fourth side 130.

With continued reference to FIGS. 2 and 3, the grommet 110 further includes a head 170 extending outwardly from the first side 124 of the body 120, and particularly from the contact surface 154 of the first side 124. As shown, the head 170 includes a base 172, which is spaced inwardly from a peripheral edge 174 of the contact surface 154, and a body 176 provided on the base 172. A retention member 178 extends outwardly from at least one side wall of the body 174. Particularly, according to one aspect, the body 174 includes a first side wall 180 and a second side wall 182 opposite the first side wall 180. The first and second side walls 180, 182 are oriented substantially perpendicular to the third and fourth sides 128, 130 of the body 120. The retention member 178 projects substantially perpendicularly from the first side wall 180. A second retention member 184 projects substantially perpendicularly from the second side wall 184. The second retention member 184 can be shaped identical to the first retention member 178, and in the illustrated embodiment, each of the first and second retention can be generally rectangular shaped in cross-section; although, this is not required. It should be appreciated that the base 172 can be positioned on the first side 124 of the body 120 such that the first and second side walls 180, 182 are oriented substantially parallel to the third and fourth sides 128, 130. With this orientation, the retention members 178, 184 extend outwardly in the same direction as the respective first and second buttresses 122, 138. As will be discussed below, the retention members 178, 184 assist in retaining the connection of the grommet 110 to a housing 190 of the second electronic device 104.

The grommet 110 further includes an elongated channel or passage 194 extending through the body 120 and the head 170. As best depicted in FIG. 2, the channel 194 is defined by an inner wall 196 of the body 120. The inner wall 196 can have a stepped configuration such that the channel 194 can be separated into a first section 200 and a second section 202. The first section 200 is dimensioned to receive an end portion 206 of the strain relief 118, and the second section 202 is dimensioned to receive the cable 112. As shown, a ledge 208 provided on the inner wall 196 defines the stepped configuration and can serve as an abutment for the end portion 206 of the strain relief 118. As best depicted in FIG. 3, the body 120 extends outward in a direction transverse from an axis 210 defined by the channel 194 a first distance and the head 170 extends outward in the transverse direction a second distance which is shorter than the first distance. Further, each of the retention members 178, 184 extends outward in the transverse direction a third distance which is shorter than the first distance. This dimensioning provides for a compact and robust grommet 110 for the electronic device 102.

FIG. 4 depicts an exemplary grommet 110′ for use with the electronic device 102 or OBD cable 102 according to another aspect of the present disclosure. Similar to grommet 110, grommet 110′ comprises a body 120′ including a first side 124′, a second side 126′ opposite the first side 124′, a third side 128′, and a fourth side 130′ opposite the third side 128′. The grommet 110′ further includes a first buttress 122′ and a second buttress 138′ opposite the first buttress. The first buttress 122′ extends outward and along a length of the third side 128′ of the body 120′. The second buttress 138′ extends outward and along a length of the fourth side 130′ of the body 120′. The second buttress 138′ can be shaped identical to the first buttress 122′, and in the illustrated embodiment, each of the first and second buttresses 122′, 138′ extends outward a first length adjacent the first side 124′ and a shorter second length adjacent the second side 126′. The first and second buttresses 122′, 138′ can be formed integrally with the body 120′ to define a one-piece grommet 110′. The first buttress 122′ is spaced inwardly from an edge 162′ of the third side 128′. Similarly, the second buttress 138′ is spaced inwardly from an edge 166′ of the fourth side 130′. As shown, and according to the exemplary embodiment, the first and second buttresses 122′, 138′ at least partially define an end face 212 of the grommet 110′. The grommet 110′ further includes a head 170′ having a configuration similar to head 170 of grommet 110. Accordingly, the head 170′ includes a base 172′ and a body 176′ provided on the base. Retention members 178′, 184′ extend outwardly from side walls of the body 174′. An elongated channel or passage 194′ extends through the body 120′ and the head 170′. A first section of the passage 194′ receives an end portion of the strain relief 118 and a second section of the passage 194′ receives the cable 112. Because the structure of grommet 110′ is similar to that of grommet 110, it should be appreciated that grommet 110′ can be used in a manner similar to the use of grommet 110 described below.

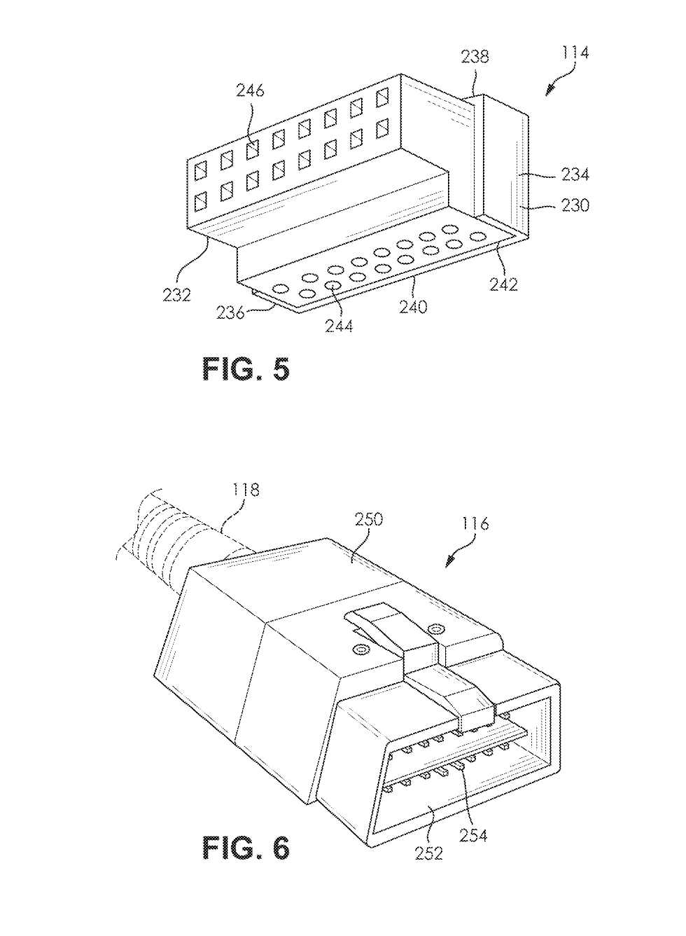

With reference back to FIGS. 1 and 2, as indicated previously, the electronic device or OBD cable 102 includes the plurality of removable and replaceable components that allow the electronic device 102 to be repaired. The cable 112 has a first end 220 and a second end 222. The first connector 114 is coupled to the cable first end. In the depicted embodiment of FIG. 5, the first connector 114 is a side socket connector or multiple pin connector including a base 230 and a replaceable body 232. The base 230 includes opposed side walls 234, 236, a top wall 238, a forward wall 240. The walls define a slot 242 for releasably receiving the body 232. The body 232 is provided with first terminals 244 for receiving wires of the cable 112 and second terminals 246 which connect to the second electronic device or off-board diagnostic device 104. As shown, the first connector 114 is a right angle connector with the first terminals 244 oriented perpendicular to the second terminals 246; although, this is not required. For example, the first connector 114 can be a straight connector with the first terminals 244 aligned with the second terminals 246. The second connector 116 is coupled to the cable second end. In the depicted embodiment of FIG. 6, second connector 116 is a multiple pin connector which includes a housing 250 connected to the strain relief 118 and an opening 252 which receives replaceable floating pins 254. The second connector 116 connects to a vehicle data bus. The pair of strain reliefs 118 is provided on the cable 112 adjacent to each of the first and second connectors 114, 116. The grommet 110 interfaces or is associated with the first connector 114 which allows for the addition of the more robust and replaceable strain relief 118. The housing 190 of the second electronic device 104 includes an aperture 260 dimensioned to at least partially releasably receive the head 170 of the grommet 110. Once inserted into the aperture 260, the retention members 178, 184 of the head 170 can releasably engage an inner surface 262 of the housing 190. This positions the body 120 of the grommet 110 entirely outside of the housing 190 with the contact surface 154 of the first side 124 and the respective surfaces 150, 152 of the second sides 146, 148 of the first and second buttresses 122, 138 in engagement with an outer surface 264 of the housing 190.

The present disclosure further provides a method of installing the first electronic device or electrical cord 102 to the housing 190 of the second electronic device 102. The method generally comprises providing the removable grommet 110 on the cable 118. Again, the grommet 110 comprises the body 120, the head 170 extending from the body 120, the channel 194 extending through the body 120 and the head 170, and at least one buttress extending substantially perpendicularly outward from the body 120. The at least one buttress is defined by the first buttress 122 and the second buttress 138 which can be a mirror image of the first buttress along the axis 210 defined by the channel 194. The method further includes inserting the first end 220 of the cable 112 through the channel 194 of the grommet 110; connecting the first end 220 of the cable 112 to the housing 190; and inserting the head 170 of the grommet 110 into the corresponding aperture 260 provided on the housing 190. The method further includes engaging the outer wall 264 of the housing 190 with the first and second buttresses 122, 138 of the grommet 110 and inserting the outwardly extending retention members 178, 184 of the head 170 in the aperture 260 of the housing 190 of the second electronic device 104, the retention members releasably engaging the inner surface 262 of the housing 190.

It will be appreciated that various of the above-disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A grommet for a modular electronic device comprising:
a body including a first side and a second side opposite the first side;
a head extending from the first side of the body;
a channel extending through the body and the head; and
at least one buttress extending outward and along a length of the body, the buttress extending outward a first length adjacent the first side and a shorter second length adjacent the second side.

2. The grommet of claim 1, wherein the at least one buttress includes a first buttress and a second buttress opposite the first buttress.

3. The grommet of claim 2, wherein the body includes a third side and a fourth side opposite the third side, the first buttress extending outward and along a length of the third side of the body, the second buttress extending outward and along a length of the fourth side of the body.

4. The grommet of claim 2, wherein the first buttress and second buttress are located on the respective third side and fourth side and at least partially define an end face of the body.

5. The grommet of claim 2, wherein each of the first and second buttresses is generally triangular shaped.

6. The grommet of claim 1, wherein the body is generally rectangular shaped.

7. The grommet of claim 1, wherein the body extends outward in a direction transverse from an axis defined by the channel a first distance and the head extends outward in the transverse direction a second distance which is shorter than the first distance.

8. The grommet of claim 7, wherein the head includes a retention member, the retention member extends outward in the transverse direction a third distance which is shorter than the first distance.

9. The grommet of claim 1, wherein the first side of body defines a contact surface, the head extends outwardly from the contact surface and is spaced inwardly from a peripheral edge of the contact surface, and the at least one buttress includes a surface which is coplanar with the contact surface.

10. The grommet of claim 1 in combination with a modular electrical device, the electronic device including a housing having an aperture dimensioned to releasably receive the head of the grommet.

11. The combination of claim 10, wherein the modular electrical device is an on-board diagnostic cable including a plurality of removable and replaceable components that allow the cable to be repaired, the replaceable components including a cable having a first end and a second end, a first connector coupled to the cable first end, a second connector coupled to the cable second end, and at least one strain relief provided on the cable adjacent to one of the first and second connectors, wherein the grommet interfaces with one of the first and second connectors.

12. An electronic device comprising:
a housing including an aperture therein;
a grommet comprising:
a body positioned entirely outside of the housing,
a head extending from the body, the head being at least partially received in the aperture of the housing,
a passage extending through the body and head, and
at least one buttress extending substantially perpendicularly outward from the body and engagable with an outer wall of the housing; and
a cable extending through the passage.

13. The electronic device of claim 12, wherein the body includes a first side and a second side opposite the first side, the buttress extending outward a first length adjacent the first side and a shorter second length adjacent the second side.

14. The electronic device of claim 13, wherein the at least one buttress includes a first buttress and a second buttress which is a mirror image of the first buttress along an axis defined by the channel.

15. The electronic device of claim 14, wherein the buttress is generally triangular shaped.

16. The electronic device of claim 13, wherein a side of the head includes an outwardly extending retention member which is received in the aperture of the housing.

17. The electronic device of claim 12, wherein the electrical device further includes a plurality of removable and replaceable components including a first connector coupled to a first end of the cable and to the housing, a second connector coupled to a second end of the cable, and at least one strain relief provided on the cable adjacent to one of the first and second connectors.

18. A method of installing an electrical cord to an electronic device housing comprising:
providing a removable grommet on the cable, the grommet comprising a body, a head extending from the body, a channel extending through the body and the head, and at least one buttress extending substantially perpendicularly outward from the body;
inserting a first end of the cable through the channel of the grommet;
connecting the first end of the cable to the housing; and
inserting the head of the grommet into a corresponding aperture provided on the housing.

19. The method of claim 18, further comprising engaging an outer wall of the housing with the buttress of the grommet.

20. The method of claim 18, wherein the head of the grommet includes a outwardly extending retention member, and further comprising inserting the retention member in the aperture of the housing.
